(19) United States
(12) Patent Application Publication
(10) Pub. No.: US 2026/0050222 A1
(43) Pub. Date: Feb. 19, 2026

(54) OPTICAL PROXIMITY CORRECTION (OPC) METHOD, AND MASK MANUFACTURING METHOD COMPRISING THE OPC METHOD

(71) Applicant: SAMSUNG ELECTRONICS CO., LTD., Suwon-si (KR)

(72) Inventors: Jinho MUN, Suwon-si (KR); Ingyun CHUNG, Suwon-si (KR)

(73) Assignee: SAMSUNG ELECTRONICS CO., LTD., Suwon-si (KR)

(21) Appl. No.: 19/063,913

(22) Filed: Feb. 26, 2025

(30) Foreign Application Priority Data
Aug. 13, 2024 (KR) 10-2024-0108491

(51) Int. Cl. G03F 7/00; G03F 1/36

(52) U.S. Cl. CPC G03F 7/70441; G03F 1/36; G03F 7/70633; G03F 7/706845

(57) ABSTRACT

An optical proximity correction (OPC) method according to an embodiment may include obtaining a first OPCed design layout by performing a first OPC on a target design layout; identifying whether an interval between neighboring patterns in the first OPCed design layout complies with a mask rule check (MRC); and removing a portion of patterns, among the neighboring patterns, that are determined to not comply with the MRC, such that a distance between the patterns complies with the MRC after the portion is removed.

### CROSS-REFERENCE TO RELATED APPLICATION

This application is based on and claims priority under 35 U.S.C. § 119 to Korean Patent Application No. 10-2024-0108491, filed on Aug. 13, 2024, in the Korean Intellectual Property Office, the disclosure of which is herein incorporated by reference in its entirety.

### BACKGROUND

One or more example embodiments of the disclosure relate to a mask manufacturing method, and more particularly, to an optical proximity correction (OPC) method and a mask manufacturing method using the OPC method.

In a semiconductor process, a photolithography process using a mask may be performed to form a pattern on a semiconductor substrate such as a wafer. If simply defined, a mask may be a pattern transfer body in which an opaque material pattern shape is formed on a transparent base material. To briefly explain a mask manufacturing process, first, a required circuit is designed, a layout for the circuit is designed, and then design data obtained through optical proximity correction (OPC) is transferred as mask tape-out (MTO) design data. Thereafter, a mask data preparation (MDP) is performed based on the MTO design data, and an exposure process, etc. may be performed on a mask substrate.

### SUMMARY

One or more example embodiments of the disclosure provide an optical proximity correction (OPC) method in which a margin between patterns may be improved and critical dimension (CD) targeting may be improved, and a mask manufacturing method including the OPC method.

In addition, the problems to be solved by the technical spirit of the present disclosure are not limited to the problems mentioned above, and other problems not mentioned will be clearly understood by those skilled in the art from the following description.

According to an aspect of an example embodiment of the disclosure, there is provided an OPC method including: obtaining a first OPCed design layout by performing a first OPC on a target design layout; identifying whether an interval between neighboring patterns in the first OPCed design layout complies with a mask rule check (MRC); and removing a portion of patterns, among the neighboring patterns, that are determined to not comply with the MRC, such that a distance between the patterns complies with the MRC after the portion is removed.

According to another aspect of the disclosure, there is provided an OPC method including: receiving a design layout for a target pattern; obtaining a first OPCed design layout by performing a first OPC with respect to the design layout; classifying neighboring patterns into a first group and a second group according to a relationship between locations of the neighboring patterns, the neighboring patterns being spaced apart from each other in the first OPCed design layout; identifying whether a distance between first patterns classified into the first group or second patterns classified into the second group complies with a mask rule check (MRC); and based on the distance between the first patterns or the second patterns not complying with the MRC, removing a portion of the first patterns or the second patterns such that the distance between the first patterns or the second patterns after the portion is removed complies with the MRC, wherein neighboring patterns that overlap in a vertical direction and/or a horizontal direction are classified into the first group, and wherein neighboring patterns that overlap in a diagonal direction are classified into the second group.

According to another aspect of the disclosure, there is provided a mask manufacturing method including: receiving a design layout for a target pattern; obtaining a first OPCed design layout by performing a first OPC on the design layout; classifying neighboring patterns into a first group and a second group according to a relationship between locations of the neighboring patterns, the neighboring patterns being spaced apart from each other in the first OPCed design layout; identifying whether a distance between first patterns classified into the first group or second patterns classified into the second group complies with a mask rule check (MRC); based on the distance between the first patterns or the second patterns not complying with the MRC, obtaining a final OPC layout by removing a portion of the first patterns or second portions to comply with the MRC; transmitting data for the final OPC layout as mask tape-out (MTO) design data; preparing mask data based on the MTO design data; and performing exposure on a mask substrate based on the mask data, wherein the classifying the neighboring patterns includes: identifying locations of the patterns in the first OPCed design layout; selecting the neighboring patterns based on the locations of the patterns; identifying whether the neighboring patterns overlap in a vertical direction and/or a horizontal direction; identifying whether the neighboring patterns overlap in a diagonal direction; classifying the neighboring patterns that overlap in the vertical direction and/or the horizontal direction into the first group; and classifying the neighboring patterns that overlap in the diagonal direction into the second group.

### BRIEF DESCRIPTION OF DRAWINGS

Example embodiments will be more clearly understood from the following detailed description taken in conjunction with the accompanying drawings, in which:

FIG. 1 is a flow chart schematically showing a process of an optical proximity correction (OPC) method according to an embodiment;

FIG. 2 is a flow chart showing an example of a mask rule check (MRC) compliance checking operation of FIG. 1;

FIG. 3 is a plan view showing a pattern of an optical proximity corrected (OPCed) design layout according to an embodiment;

FIG. 4 is a plan view showing a pattern of an OPCed design layout according to another embodiment;

FIG. 5 is a flow chart showing an example operation of partially removing the pattern of FIG. 1;

FIG. 6 is a flow chart showing an example operation of removing a portion of patterns that are overlapped in vertical and horizontal directions of FIG. 5;

FIG. 7 is a flow chart showing an example operation of setting a correction target region of FIG. 6;

FIG. 8 is a layout diagram of patterns to explain an operation of setting a correction target region of FIG. 6;

FIG. 9 is a graph showing an area of a correction target region according to a location of an origin and an angle of an interval vector according to the location of the origin according to an embodiment;

FIG. 10 is a graph showing an area of a correction target region according to an angle of the interval vector according to an embodiment;

FIG. 11 is a diagram showing a simulation contour of the related art and an embodiment of the disclosure;

FIG. 12 is a graph showing a process window margin of the related art and an embodiment of the disclosure;

FIG. 13 is a flow chart showing an example operation of removing a portion of diagonally overlapped patterns of FIG. 5;

FIG. 14 is a flow chart showing an example operation of setting a correction target region of FIG. 13;

FIG. 15 is a pattern layout diagram to explain the operation of setting the correction target region of FIG. 14;

FIG. 16 is a graph showing an area of a correction target region and an angle of an interval vector according to a location of an origin according to an embodiment;

FIG. 17 is a graph showing a height and a length of a base of a correction target region according to an angle of an interval vector according to an embodiment;

FIG. 18 is a plan view showing patterns from which a portion of diagonally overlapped patterns is removed according to an embodiment;

FIG. 19 is a plan view showing patterns from which a portion of the patterns is removed, according to the related art;

FIG. 20 is a flow chart schematically showing a process of an OPC method according to another embodiment;

FIG. 21 is a flowchart schematically showing an operation of classifying patterns of FIG. 20 into a first group or a second group;

FIG. 22 is a flowchart schematically illustrating an MRC compliance check operation of FIG. 20;

FIG. 23 is a flowchart schematically illustrating an operation of removing a portion of the pattern of FIG. 20;

FIG. 24 is a flowchart schematically illustrating an operation of removing a portion of patterns of the first group of FIG. 23;

FIG. 25 is a flowchart schematically illustrating an operation of setting a correction target region of FIG. 24;

FIG. 26 is a flowchart schematically illustrating an operation of removing a portion of the patterns of the second group of FIG. 23;

FIG. 27 is a flowchart schematically illustrating an operation of setting a correction target region of FIG. 26; and

FIG. 28 is a flowchart schematically illustrating a method of manufacturing a mask according to an embodiment.

### DETAILED DESCRIPTION

Hereafter, example embodiments of the disclosure will be fully described with reference to the accompanying drawings In the drawings, like reference numerals are used to indicate like elements and the descriptions thereof will not be repeated.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

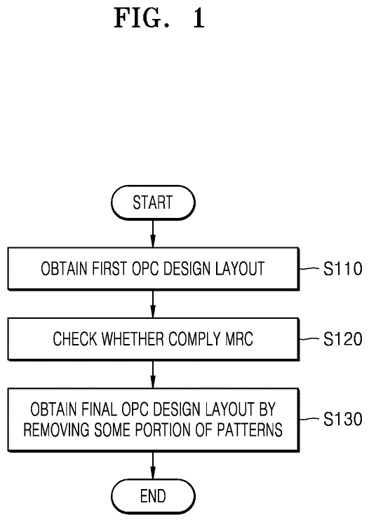

FIG. 1 is a flow chart schematically showing a process of an optical proximity correction (OPC) method according to an embodiment.

Referring to FIG. 1, the OPC method according to an embodiment may first apply a first OPC to an OPC target design layout to obtain a first optical proximity corrected (OPCed) design layout (S110). Here, the OPC target design layout may denote a design layout for a target pattern to be formed on a substrate, such as a wafer. The target pattern on the substrate may be formed by transferring a pattern on a mask to the substrate through an exposure process. Therefore, the OPC target design layout may denote a layout for a pattern on a mask corresponding to the target pattern on the substrate. Because the pattern on the mask is reduced and projected and transferred onto the wafer, the pattern on the mask may have a larger size than a target pattern on the substrate.

The first OPC may denote a baseline OPC or a commercial OPC generally used in a mask manufacturing method. Meanwhile, in the OPC method according to an embodiment, a second OPC may be a concept that includes all operations performed to partially remove a pattern of an OPC layout to comply with a mask rule check (MRC) described later for the first OPCed design layout. Accordingly, a second OPCed design layout may be obtained by performing the second OPC on the first OPCed design layout.

In detail, operation S110 of obtaining the first OPCed design layout may first receive a design layout for a target pattern to be formed on a substrate. Here, the target pattern may denote a pattern to be formed on a Si substrate such as a wafer. In other words, the pattern on the mask may be transferred to the substrate through an exposure process, and thus, the target pattern may be formed on the substrate. Because the pattern on the mask is generally reduced and transferred onto a wafer, the pattern on the mask may have a larger size than the target pattern on the substrate.

The design layout may denote a layout for a pattern on the mask corresponding to the target pattern. Due to characteristics of exposure process, a shape of the target pattern on the wafer and a shape of an actual pattern on the mask used in the exposure process may be different. However, a form of the first design layout for the pattern on the mask may be substantially the same as a form of the target pattern.

After the design layout is input, the first OPCed design layout may be obtained by performing the first OPC on the design layout. The first OPC refers to a related art OPC for implementing patterning closest to the target pattern on the substrate. For reference, as the patterns become finer, an optical proximity effect (OPE) may occur due to an influence between neighboring patterns during the exposure process. The OPC may be a method of suppressing the OPE occurrence by correcting the design layout of patterns on a mask.

An overall explanation about the process of the first OPC, which is a basic OPC, is provided. The first OPC process may be largely divided into two processes. The one is a rule-based OPC process and the other one is a simulation-based OPC or a model-based OPC process. The model-based OPC process may be advantageous in terms of time and cost because the model-based OPC process uses only measurement results of representative patterns without having to measure all of a large number of test patterns.

The first OPC process may include a method of adding sub-lithographic features called serifs on corners of the pattern as well as a method of adding sub-resolution assist features (SRAFs) such as scattering bars in addition to the modification of a pattern layout.

The performance of the first OPC process may include first preparing basic data for OPC. Here, the basic data may include data on a shape of a pattern of a sample, a location of the pattern, a type of measurement such as a measurement of a space or a line of the pattern, and a basic measurement value. In addition, the basic data may include information such as a thickness, a refractive index, and a dielectric constant of a photoresist (PR) and may include a source map for a shape of an illumination system. It should be noted that the basic data is not limited to examples of the data described above.

After preparing the basic data, an optical OPC model may be generated. The generation of the optical OPC model may include optimization of a defocus stand (DS) position, the best focus (BF) position, etc. in the exposure process. In addition, the generation of the optical OPC model may include generation of an optical image considering a diffraction phenomenon of light and/or an optical state of an exposure equipment itself. The generation of the optical OPC model is not limited thereto. For example, the generation of the optical OPC model may include various contents related to an optical phenomenon in the exposure process.

After generating the optical OPC model, an OPC model for a PR may be generated. The generation of the OPC model for the PR may include optimization of a threshold value of the PR. Here, the threshold value of the PR denotes the threshold value at which a chemical change occurs in the exposure process, and, for example, the threshold value may be expressed using intensity of exposure light. The generation of the OPC model for the PR may also include selecting an appropriate model form from several PR model forms.

The optical OPC model and the OPC model for the PR may be generally referred to as the OPC model. After generating the OPC model, an OPC pattern, that is, an OPCed design layout may be obtained by performing a simulation using the OPC model. Thereafter, the OPCed design layout may be transferred to a mask manufacturing team as mask tape-out (MTO) design data for mask manufacturing.

The process of obtaining the OPC pattern may include a process of minimizing an edge placement error (EPE) by comparing a simulation contour with a target pattern. Here, the EPE denotes a difference between an edge of the target pattern and the simulation contour, and the EPE may generally be calculated at each of set evaluation points. The simulation contour may be a result of simulation using the OPC model and may correspond to a shape of the target pattern formed on a wafer in an exposure process using a mask. Accordingly, making the simulation contour as similar as possible to the shape of the target pattern may correspond to the purpose of the OPC process.

The process of minimizing may be EPE may be performed such that, after calculating the EPE, a new OPC pattern may be obtained by moving segments such that the EPE is reduced, and then, the EPE is calculated again by comparing the simulation contour with the target pattern. Generally, the process of minimizing the EPE may be repeated until the EPE becomes less than or equal to a set reference value or may be repeated for a set number of repetitions. For reference, the segment may be referred to as a fragment, and may denote a straight line corresponding to an edge of a design layout, or data about the line. The edge of the design layout may be divided into multiple segments according to a predetermined division rule. A length of the segment, the division rule, etc. may be set by a user performing the OPC method.

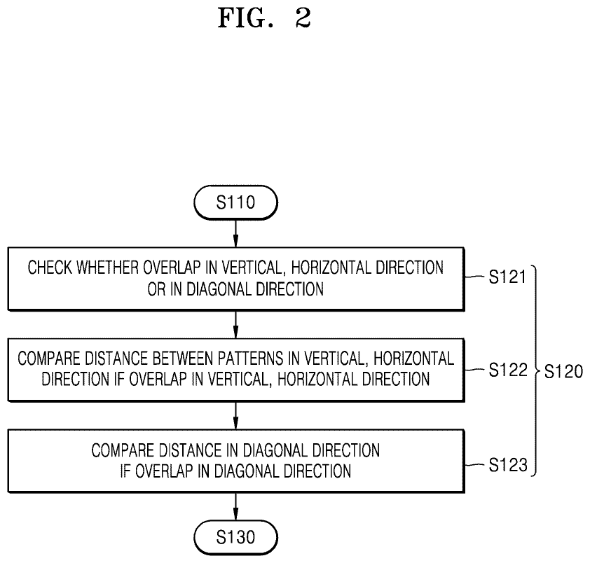

Afterwards, it may be checked whether the first OPCed design layout complies with the MRC (S120). Checking compliance with the MRC may mean checking whether the OPCed design layout complies with the set mask rule in order to produce a mask. Operation S120 of checking the MRC compliance is described in more detail in the description with reference to FIG. 2.

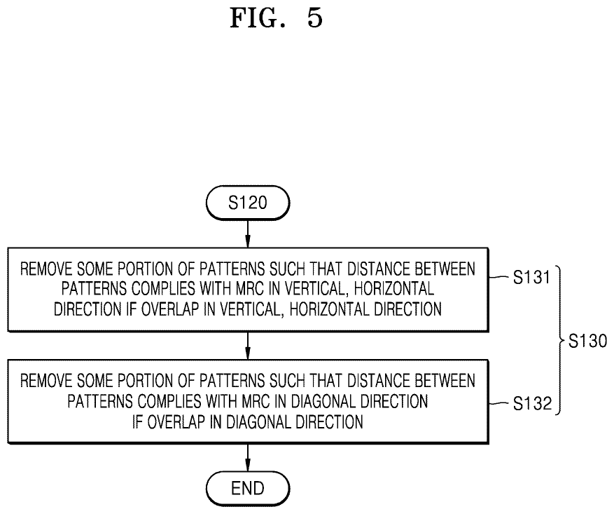

If the first OPCed design layout does not comply with the MRC, a portion of a pattern in the first OPCed design layout may be removed such that the first OPCed design layout complies with the MRC, and then, a final OPCed design layout may be obtained (S130). Operation S130 of removing a portion of the pattern to obtain the final OPCed design layout is described in more detail in the description with reference to FIG. 5.

FIG. 2 is a flow chart showing an example of an MRC compliance checking operation of FIG. 1. The MRC compliance checking operation S120 may include operation S121 of checking (or identifying) whether patterns overlap in a vertical direction and/or a horizontal direction and/or in a diagonal direction (or at least one of a vertical direction, a horizontal direction, and a diagonal direction), operation S122 of checking whether a distance between the patterns in the vertical direction and/or a horizontal direction complies with the MRC in the a case where the patterns overlap in the vertical direction and/or the horizontal direction, and operation S123 of checking whether a distance between the patterns in the diagonal direction complies with the MRC in a case where the patterns overlap in the diagonal direction.

Operation S121 of checking whether the patterns overlap in the vertical and/or horizontal direction and/or in the diagonal direction may check whether adjacent patterns in the first OPCed design layout overlap in the vertical and/or horizontal direction and/or in the diagonal direction.

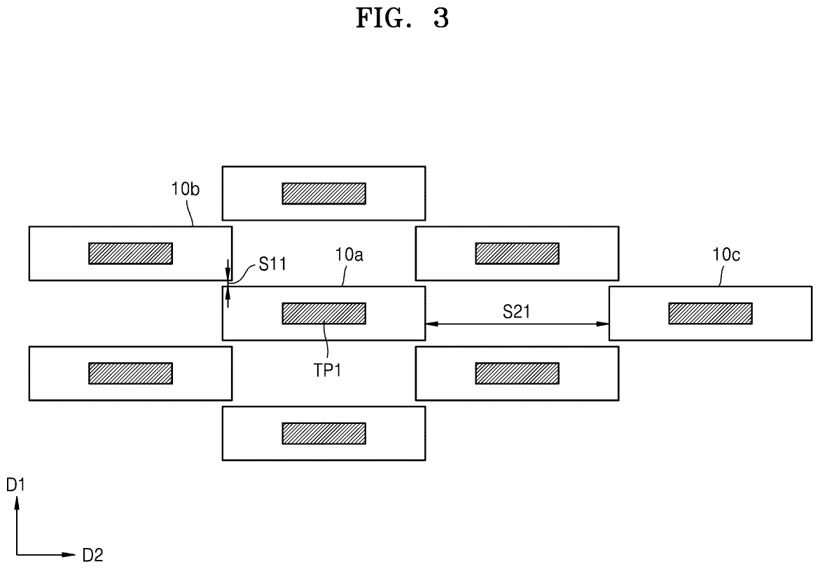

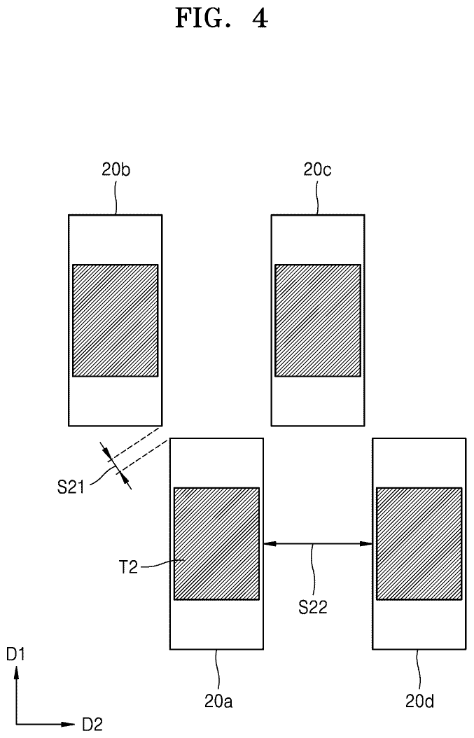

FIG. 3 and FIG. 4 are each a plan view showing a pattern of an embodiment of the first OPCed layout. That is, FIG. 3 is a plan view showing a case where the patterns of the first OPCed layout overlap in the vertical and/or horizontal direction, and FIG. 4 is a plan view showing a case where the patterns of the first OPCed layout overlap in the diagonal direction.

Referring to FIG. 3, a pattern 10a may overlap with a neighboring pattern 10b in a vertical direction D1. The overlapping of neighboring patterns 10a, 10b, and 10c in the vertical direction D1 or a horizontal direction D2 denotes that when the pattern 10a moves in the vertical direction D1 or the horizontal direction D2, the pattern 10a overlaps with another pattern 10b or 10c. Specifically, if the pattern 10a moves in the vertical direction D1, the pattern 10a overlaps with the pattern 10b located in the vertical direction D1 in some area of the pattern 10a, and in this case, it may be said that the neighboring patterns 10a and 10b overlap in the vertical direction D1.

The neighboring patterns 10a and 10c may overlap in the horizontal direction D2. That is, if the pattern 10a moves in the horizontal direction D2, the pattern 10a overlaps with the pattern 10c in some area of the pattern 10a, and thus, it may be said that the pattern 10a and the pattern 10c overlap in the horizontal direction D2.

As described above, operation S121 of checking whether the patterns overlap may include checking whether the pattern 10a of the first OPCed layout overlaps with any of the neighboring patterns 10b and 10c by moving the pattern 10a in the vertical direction D1 or the horizontal direction D2.

Referring to FIG. 4, a pattern 20a may overlap with a neighboring pattern 20b in the diagonal direction. If the pattern 20a is moved in a direction that is between the vertical direction D1 and the horizontal direction D2, that is, in the diagonal direction, rather than in the vertical direction D1 or the horizontal direction D2, the pattern 20a may overlap with the pattern 20b located diagonally. In this way, if the pattern 20a is moved in the diagonal direction and overlaps with the neighboring pattern 20b, the pattern 20a may be determined to overlap with the neighboring pattern 20b in the diagonal direction. In addition, the pattern 20a may overlap with a pattern 20c located in another diagonal direction.

That is, operation S121 of checking whether there is an overlap between the patterns may include checking whether the pattern 20a of the first OPCed layout overlaps with the neighboring pattern 20b and 20c in the diagonal direction by moving the pattern 20a in the diagonal direction.

After checking whether the neighboring patterns in the vertical and/or horizontal direction overlap each other, if the neighboring patterns overlap in the vertical and/or horizontal direction, it may be checked whether a distance between the neighboring patterns in a region where the neighboring patterns overlap in the vertical and/or horizontal direction complies with the MRC (S122).

As described above, in the layout illustrated in FIG. 3, the patterns 10a and 10b may overlap in the vertical direction D1 and overlap in the horizontal direction D2. In operation S112, a distance S11 between the overlapping patterns 10a and 10b in the vertical direction D1 may be checked, and it may be checked whether the distance S11 between the overlapping patterns 10a and 10b in the vertical direction D1 complies with the MRC. If the distance S11 between the neighboring patterns 10a and 10b is less than a predetermined distance, it is determined that the patterns 10a and 10b do not comply with the MRC, and if the distance S11 between the neighboring patterns 10a and 10b is greater than the predetermined distance, it may be determined that patterns 10a and 10b comply with the MRC.

For example, if the predetermined distance of the MRC is 12 nm and the distance S11 between adjacent patterns 10a and 10b in the vertical direction D1 is 7.6 nm, the distance S11 between adjacent patterns 10a and 10b in the vertical direction D1 is less than the predetermined distance of the MRC, and therefore, it may be determined that the adjacent patterns 10a and 10b in the vertical direction D1 do not comply with the MRC. A portion of the patterns 10a and 10b that do not comply with the MRC may be removed to comply with the MRC. A process of removing the portion of the patterns according to an embodiment will be described in more detail later.

Because the patterns 10a and 10c overlap in the horizontal direction D2, a distance S21 between the patterns 10a and 10c may be detected and compared with a predetermined distance of the MRC. If the distance S21 between the patterns 10a and 10c is greater than the predetermined distance of MRC, the distance S21 between the patterns 10a and 10c in the horizontal direction D2 may be determined to comply with the MRC.

FIG. 5 is a flow chart showing an example operation of partially removing the pattern of FIG. 1.

Referring to FIG. 5, operation S130 of removing a portion of the patterns may include, for example, operation S131 of removing a portion of the patterns such that remaining patterns that overlap in the vertical and/or horizontal direction comply with the MRC and operation S132 of removing a portion of the patterns such that remaining patterns that overlap in the diagonal direction comply with the MRC.

Operation S131 of removing a portion of the patterns such that the remaining patterns that overlap in the vertical and/or horizontal direction comply with the MRC may remove a portion of the patterns such that, when remaining adjacent patterns overlap in the vertical and/or horizontal direction, the distance between the remaining adjacent patterns in the overlapping region in the vertical and/or horizontal direction complies with the MRC.

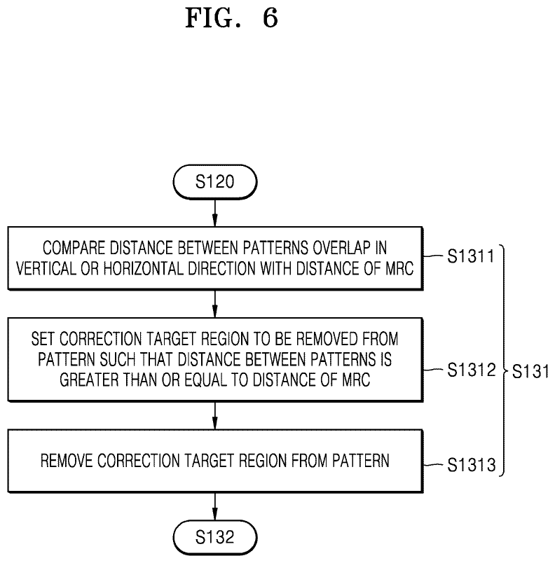

FIG. 6 is a flow chart showing an example operation of removing a portion of the patterns that are overlapped in vertical and horizontal directions of FIG. 5.

Referring to FIG. 6, the operation S131 of removing a portion of patterns such that vertically and/or horizontally overlapping patterns comply with the MRC may include operation S1311 of comparing a distance between the patterns with a predetermined distance of the MRC, operation S1312 of setting a correction target region to be removed from a corresponding pattern if the distance between the patterns is less than the predetermined distance of the MRC, such that the distance between the patterns after the removal is greater than or equal to the predetermined distance of the MRC, and operation S1313 of removing the correction target region from the pattern.

Operation S1311 of comparing the distance between patterns with the predetermined distance of the MRC may detect the distance between neighboring patterns that overlap in the vertical direction D1 or the horizontal direction D2 as described above and compare the distance between neighboring patterns with the predetermined distance of MRC.

If the distance between neighboring patterns that overlap in the vertical direction D1 or the horizontal direction D2 is less than the predetermined distance of the MRC, the patterns do not comply with the MRC. Operation S1312 may set a correction target region for each of the neighboring patterns in the vertical direction D1 or the horizontal direction D2. If the correction target region is removed from the patterns, the distance between the patterns may comply with the MRC.

Operation S1312 of setting the correction target region may set the correction target region for each pattern such that the distance between the patterns is greater than or equal to a predetermined distance of the MRC after the removal of the correction target region, while the area of the correction target region is minimized.

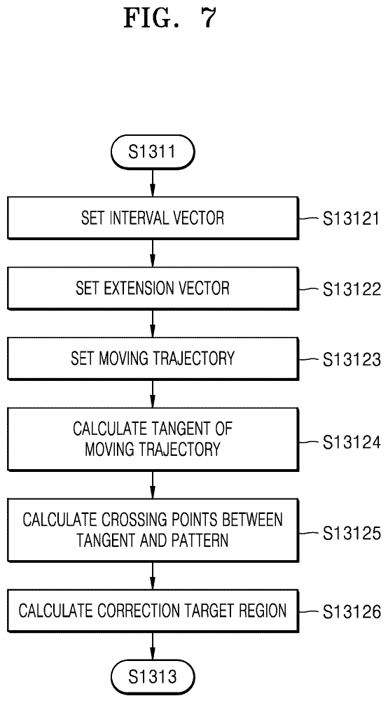

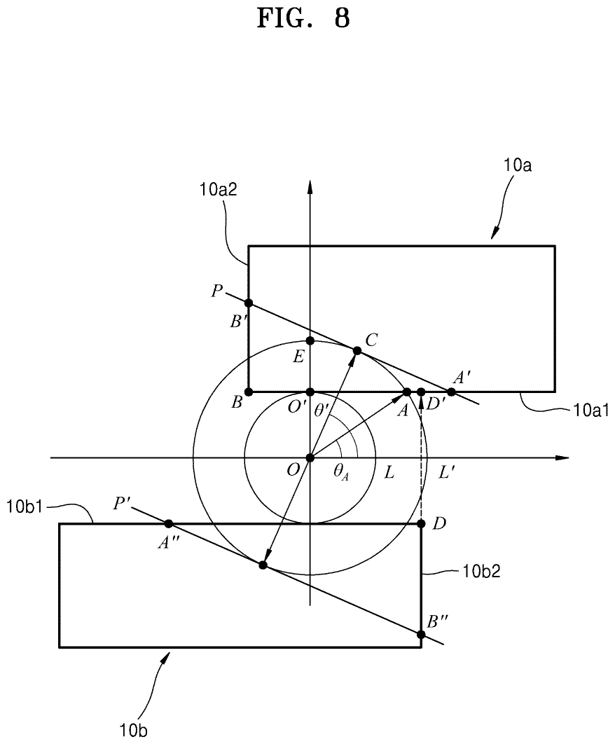

FIG. 7 is a flow chart showing an example operation S1312 of setting a correction target region of FIG. 6, and FIG. 8 is a layout diagram of patterns to explain operation S1312 of setting a correction target region of FIG. 6.

Referring to FIG. 7, operation S1312 of setting the correction target region may first set an interval vector between overlapping neighboring patterns (S13121). In detail, the interval vector may have a starting point within a region where patterns overlap in the vertical and/or horizontal direction, may have a direction in which the distance between the patterns is minimum, and may have a size of ½ of the minimum distance between the patterns.

Referring to FIG. 8, operation S13121 may set a starting point O of the interval vector in a region between neighboring patterns 10a and 10b between a bottom side 10a1 of the pattern 10a and a top side 10b1 of the pattern 10b. The starting point O of the internal vector may be located in a region in which the bottom side 10a1 and the top side 10b1 overlap in the vertical direction. The starting point O of the interval vector may be located in a region between the bottom side 10a1 of the pattern 10a and the top side 10b1 of the pattern 10b, and a region between a left side 10a2 of the pattern 10a to the left and a right side 10b2 of the pattern 10b to the right.

A length in the horizontal direction of the region where the bottom side 10a1 of the pattern 10a and the top side 10b1 of the pattern 10b overlap in the vertical direction may be the same as a length between the left side 10a2 of the pattern 10a and the right side 10b2 of the pattern 10b and may be a length of a line segment B̅D̅′̅. The length of the line segment B̅D̅′̅ may be set to k.

The size of the interval vector may be ½ of the distance between the patterns 10a and 10b in a direction at which the distance between the patterns 10a and 10b is minimum. The distance between the patterns 10a and 10b at which the distance is minimum may be the vertical distance between the bottom side 10a1 of the pattern 10a and the top side 10b1 of the pattern 10b. A line segment O̅O̅′̅ may be perpendicular to the bottom side 10a1 of the pattern 10a and the top side 10b1 of the pattern 10b, and if the line segment O̅O̅′̅ is ½ of a vertical distance between the bottom side 10a1 of the pattern 10a and the top side 10b1 of the pattern 10b, a length L of the line segment O̅O̅′̅ may be the size of the interval vector. Operation S1312 may set the length L of the line segment O̅O̅′̅ to the size of the interval vector.

The interval vector may have a direction from the starting point O toward the bottom side 10a1 of the pattern 10a.

An angle formed by the interval vector with an X-axis may be θ′. θ′ may have a range from 0° to 360°, and as θ′ changes from 0° to 360°, a trajectory indicated by an end point of the interval vector may be a circle having the starting point O of the interval vector as the origin and the size L of the interval vector as a radius. The circle may contact the bottom side 10a1 of the pattern 10a and the top side 10b1 of the pattern 10b.

Next, an extension vector having the end point of the interval vector as the starting point, having the same direction as the interval vector, and having a predetermined size may be set (S13122). The size of the extension vector may be set to d. The starting point of the extension vector may be the same as the end point of the interval vector, and the direction of the extension vector may be the same as the direction of the interval vector. An angle formed by the extension vector with the X-axis may be the same as the angle θ′ that the interval vector forms with the X-axis.

Next, a moving trajectory may be set (S13123). The moving trajectory may denote a trajectory drawn by the end point of the extension vector within the patterns 10a and 10b. Specifically, θ′ may be the angle between the interval vector and the X-axis as described above and is the angle between the extension vector extended from the interval vector and the X-axis. As θ′ changes from 0° to 360°, the trajectory indicated by the end point of the extension vector may be a circle with the starting point O of the interval vector as the origin and a radius as L′, which is a sum of the size L of the interval vector and the size d of the extension vector. Because the radius of the circle formed by the end point of the extension vector is the sum of the size L of the interval vector and the size d of the extension vector, the circle may overlap with a portion of the patterns 10a and 10b as illustrated in FIG. 8. That is, some portion of the trajectory of the end point of the extension vector may be located within the patterns 10a and 10b.

Operation S13123 may set an arc [symbol] , which is a trajectory of an end point located within a range of 0° to 90° among the trajectory of the end point of the extension vector located within the patterns 10a and 10b.

Next, a tangent of the moving trajectory may be obtained (S13124). An equation for obtaining a tangent at a point C, which is the end point of a vector that is the sum of the interval vector and the extension vector, may be obtained from the following Equation 1.

$$y = - \frac{1}{tan {θ}^{′}} x + ( L + d ) \sqrt{1 + \frac{1}{{tan}^{2} {θ}^{′}}} \qquad [ Equation 1 ]$$

Here, θ′ is an angle of the interval vector with respect to the X-axis, L is the size of the interval vector, and d is the size of the extension vector.

Next, intersection points where the tangent obtained from Equation 1 meets the pattern 10a may be calculated (S13125).

The intersection point denotes a point where the tangent meets at least one side of the pattern 10a. Referring to FIG. 8, the intersection point where the tangent meets the bottom side 10a1 of the pattern 10a may be A′, and the intersection point where the tangent meets the left side 10a2 of the pattern 10a may be B′.

Coordinates of A′ may be ((L+d)\sqrt{1+tan² θ′}−L tan θ′,(L+d)sin θ_{A}) and coordinates of B′ may be

$$( - q , \frac{q + ( L + d ) \sqrt{1 , + {tan}^{2} {θ}^{′}}}{tan {θ}^{′}} ) .$$

Here, θ_{A} is an angle of the vector (the sum of the interval vector and the extension vector) with respect to the X-axis, wherein the vector has a point A where the moving trajectory [symbol] meets the bottom side 10a1 of the pattern 10a as an end point and the origin O as the starting point. θ_{A} may be obtained from Equation 2.

$${θ}_{A =} {sin}^{- 1} ( \frac{L}{L + d} ) \qquad [ Equation 2 ]$$

q is the coordinate value on the X-axis of a vertex B of the pattern 10a. q may correspond to a length of a line segment O̅′̅B̅.

Next, the correction target region may be set (S13126). The correction target region may be a region having a smallest area among regions formed by the line segment connecting the vertex B and intersection points A′ and B′ of the pattern 10a and the tangent line. The intersection points A′ and B′ may vary depending on a location of the origin O and a slope of the tangent line. Accordingly, a region formed by the line segment connecting the vertex B and intersection points A′ and B′ of the pattern 10a and the tangent line may have various sizes. The correction target region may be a region having the smallest area among the regions formed by the vertex B and the intersection points A′ and B′.

Referring to FIG. 8, a line segment B̅A̅′̅ connecting the vertex B of the pattern 10a and the intersection point A′ may be obtained from the following Equation 3.

$$\overline{{BA}^{′}} = ( L + d ) \sqrt{1 + {tan}^{2} {θ}^{′}} = ( L + d ) \sqrt{1 + {tan}^{2} {θ}^{′}} - L tan {θ}^{′} + q \qquad [ Equation 3 ]$$

A line segment B̅B̅′̅ connecting the vertex B of the pattern 10a and another intersection point B′ may be obtained from the following Equation 4.

$$\overline{{BB}^{′}} = \frac{q + ( L + d ) \sqrt{1 + {tan}^{2} {θ}^{′}}}{tan {θ}^{′}} - L \qquad [ Equation 4 ]$$

An area Sᵤₚₚₑᵣ of a region formed by the line segment B̅A̅′̅, the line segment B̅B̅′̅, and a tangent line A̅′̅B̅′̅ in the pattern 10a may be obtained from the following Equation 5.

$$[ Equation 5 ]$$

$${S}_{upper =} \frac{1}{2} \times \overline{{BA}^{′}} \times \overline{{BB}^{′}} = \frac{1}{2} ( ( L + d ) \sqrt{1 + {tan}^{2} {θ}^{′}} - L tan {θ}^{′} + q ) ( \frac{q + ( L + d ) \sqrt{1 + {tan}^{2} {θ}^{′}}}{tan {θ}^{′}} - L )$$

An area S_{lower} of the region formed by a line segment D̅A̅″̅, a line segment D̅B̅″̅, and a tangent line A̅″̅B̅″̅ in the pattern 10b may be obtained from the following Equation 6.

$$[ Equation 6 ]$$

$${S}_{lower =} \frac{1}{2} \times \overline{{DA}^{″}} \times \overline{{DB}^{″}} = \frac{1}{2} ( ( L + d ) \sqrt{1 + {tan}^{2} {θ}^{′}} - L tan {θ}^{′} + ( k - q ) ( \frac{( k - q ) + ( L + d ) \sqrt{1 + {tan}^{2} {θ}^{′}}}{tan {θ}^{′}} - L )$$

A sum Sₜₒₜₐₗ of the region Sᵤₚₚₑᵣ formed by the line segment B̅A̅′̅, the line segment B̅B̅′̅, and the tangent line A̅′̅B̅′̅ in pattern 10a and the region S_{lower} formed by the line segment D̅A̅″̅, the line segment D̅B̅″̅, and the tangent line A̅″̅B̅″̅ in pattern 10b may be obtained from the following Equation 7.

$${S}_{total} = {S}_{upper} + {S}_{lower} \qquad [ Equation 7 ]$$

The correction target region may be the region where the sum Sₜₒₜₐₗ of the area formed by the line segment B̅A̅′̅, the line segment B̅B̅′̅, and the tangent A̅′̅B̅′̅ in the pattern 10a and the area formed by the line segment D̅A̅″̅, the line segment D̅B̅″̅, and the tangent A̅″̅B̅″̅ in the pattern 10b is minimum.

A condition for the sum Sₜₒₜₐₗ of the areas to be minimum in a range in which θ′ is greater than or equal to θ_{A} and less than or equal to 90° may be that q is ½ of k. The q is, as described above, a length of the line segment O̅′̅B̅, and k is the length of the line segment B̅D̅′̅.

That is, if the condition of q=k/2 is satisfied, the region formed by the line segment B̅A̅′̅, the line segment B̅B̅′̅, and the tangent A̅′̅B̅′̅ and the region formed by the line segment D̅A̅″̅, the line segment D̅B̅″̅, and the tangent A̅″̅B̅″̅ may be set as the correction target regions.

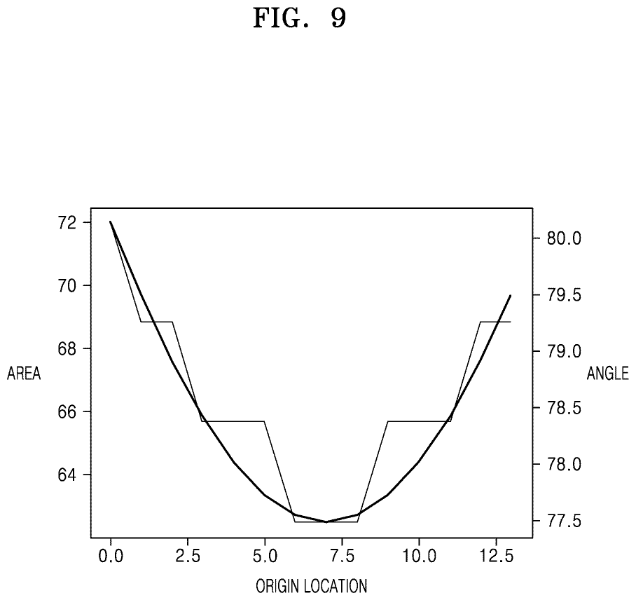

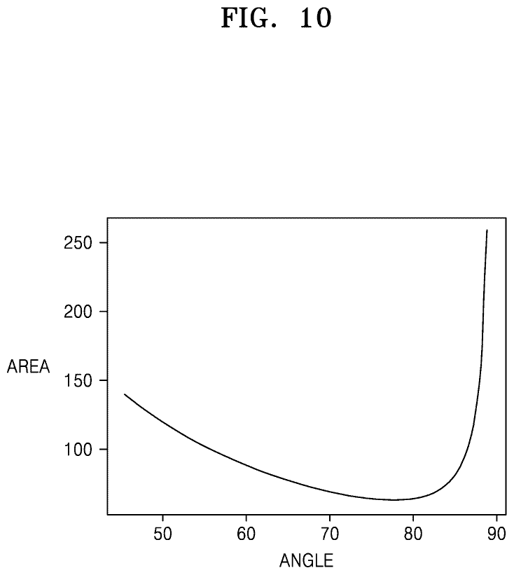

FIG. 9 is a graph showing an area of the correction target region according to the location of the origin and an angle of the interval vector according to an embodiment, and FIG. 10 is a graph showing an area of the correction target region according to the angle of the interval vector according to an embodiment.

The graphs of FIGS. 9 and 10 show a case where L, which is the size of the interval vector, is 4, d, which is the size of the extension vector, is 2, and k, which is the length of the line segment, is 14.

Referring to FIG. 9, the graph showing the area Sₜₒₜₐₗ according to the location of the origin O is a parabola. It may be confirmed that the area Sₜₒₜₐₗ and the angle θ′ are minimum when the location of the origin O is 7, which is ½ of k.

FIG. 10 is a graph showing an area Sₜₒₜₐₗ according to the angle θ′, and as confirmed in FIG. 9, the area Sₜₒₜₐₗ is minimum when the angle θ′ is 77.5 degrees.

Next, the correction target region may be removed from the pattern (S1313). As described above, the correction target region may be a region having the smallest area among the regions formed by the line segment B̅A̅′̅, the line segment B̅B̅′̅, and the tangent line A̅′̅B̅′̅ in the pattern 10a and the regions formed by the line segment D̅A̅″̅, the line segment D̅B̅″̅, and the tangent line A̅″̅B̅″̅ in the pattern 10b. Operation S1313 may form a final OPC design layout by removing the correction target region determined in operation S1312 from the patterns 10a and 10b.

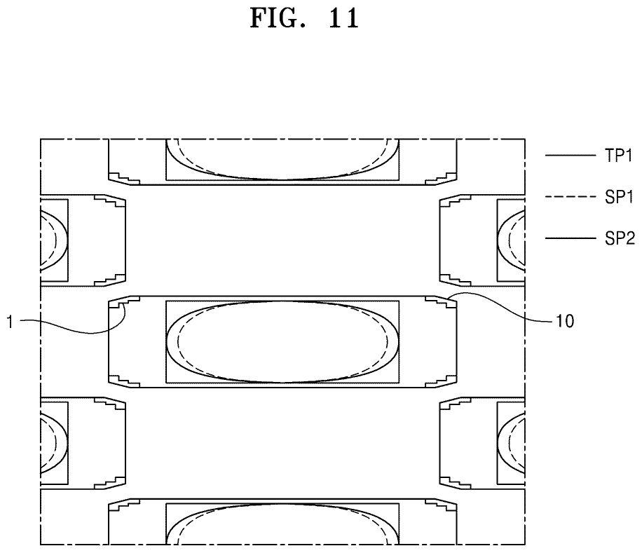

FIG. 11 is a diagram showing a simulation contour of the related art and an embodiment of the disclosure. Referring to FIG. 11, it may be confirmed that in a pattern 1, some regions are removed according to the related art in a stepwise manner. In the related art, some regions of the pattern 1 are removed in a stepwise manner until the MRC is satisfied for an entire layout. Because, in the related art, some regions of the pattern are removed without considering an arrangement relationship between patterns or an optimized angle or size for pattern removal, more regions may be unnecessarily removed than intended in the OPC. As a result, in the related art, a phenomenon may occur in which a margin between patterns decreases and critical dimension (CD) targeting decreases. In FIG. 11, it may be confirmed that a simulation pattern SP1 for the pattern 1, from which a portion of the pattern is removed in a stepwise manner according to the related art, is more different (e.g., more deviant) from a target pattern TP1 compared to a simulation pattern SP2 for a pattern 10 from which the correction target region is removed according to an embodiment.

According to an embodiment, for the patterns of the OPCed layout, an arrangement of neighboring patterns may be checked to determine whether the neighboring patterns overlap in the vertical and/or horizontal direction and/or in the diagonal direction, and then, an optimal correction target region may be set according to a case of overlapping in the vertical and/or horizontal direction and/or a case of overlapping in the diagonal direction, and the correction target region may be removed from the patterns, thereby avoiding a removal of unnecessary regions and improving a pattern margin and CD targeting. The setting of the correction target region for the diagonal overlap according to an embodiment will be described later.

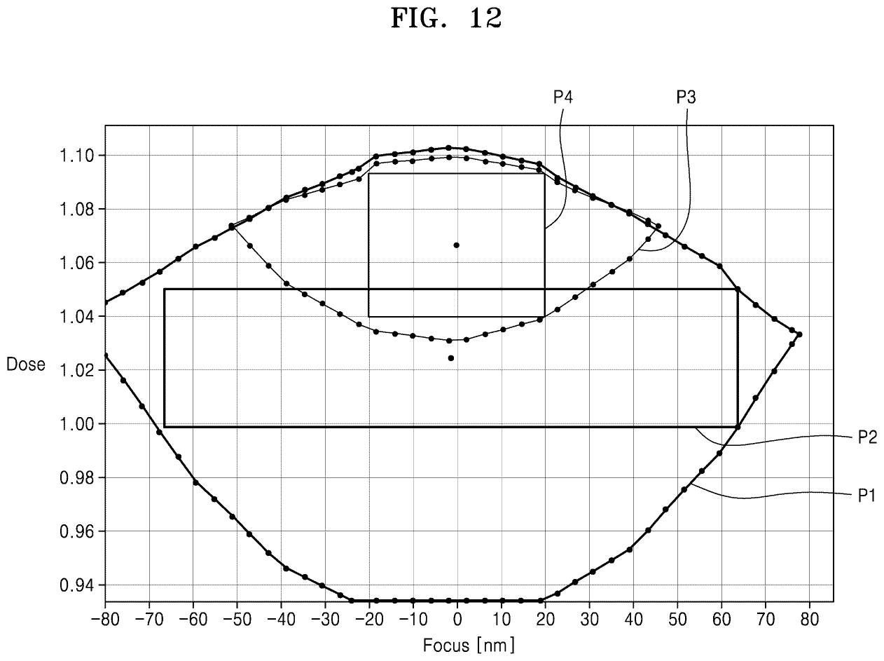

FIG. 12 is a graph showing a process window margin of the related art and the disclosure. FIG. 12 shows a relationship between focus and light intensity (dose) and may indicate a depth of focus. A distance (or width) on the X-axis of regions P2 and P4 that respectively satisfy a relationship P1 and a relationship P3 between focus and light intensity may be the depth of focus. P1 shows the relationship between the focus and light intensity for a mask manufactured as a result of generating a final OPCed layout by removing a correction target region for a pattern according to an embodiment, and P3 shows the relationship between the focus and light intensity for a mask manufactured as a result of generating a final OPCed layout by removing some regions for the pattern according to the related art. Widths of the regions P2 and P4, which are maximum regions satisfying P1 and P3 respectively, may indicate depths of focus. The region P2 may have a depth of focus of about 120 nm and the region P1 may have a depth of focus of about 40 nm. If the mask is formed according to an embodiment, it may be confirmed that the depth of focus may be improved by about three times compared to the related art.

Operation S132 (see FIG. 5) of removing a portion of the patterns such that the patterns that overlap in the diagonal direction comply with the MRC, if the adjacent patterns overlap in the diagonal direction, may remove a portion of the patterns such that a distance between the neighboring patterns in the diagonal direction complies with the MRC.

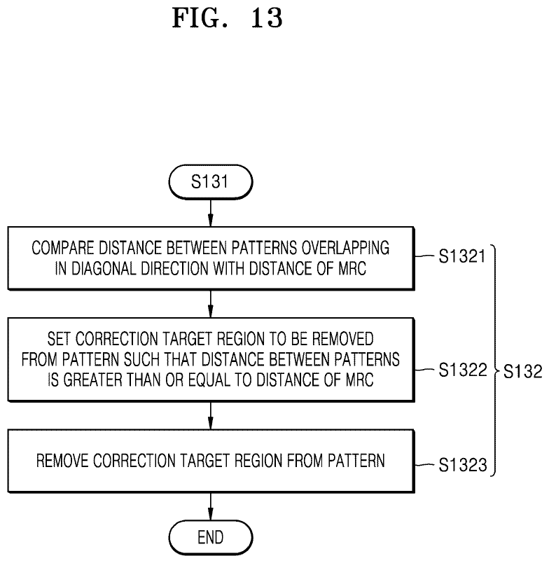

FIG. 13 is a flow chart showing an example operation of removing a portion of the diagonally overlapped patterns of FIG. 5.

Referring to FIG. 13, operation S132 of removing a portion of the patterns such that the diagonally overlapping patterns comply with the MRC may include operation S1321 of comparing the distance between the patterns that diagonally overlap with a predetermined distance of the MRC, operation S1322 of setting a correction target region to be removed from the each of the patterns if the distance between the diagonally overlapping patterns is less than the predetermined distance of the MRC such that the distance between the diagonally overlapping patterns is greater than or equal to the predetermined distance of the MRC after the removal, and operation S1323 of removing the correction target region from the pattern.

Operation S1321 of comparing the distance between patterns with the predetermined distance of the MRC may detect the distance between neighboring patterns in the diagonal direction as described above and compare the distance between the neighboring patterns with the predetermined distance of the MRC.

If the distance between the neighboring patterns in the diagonal direction is less than the predetermined distance of the MRC, the patterns may be determined as not complying with the MRC, and operation S1322 may set a correction target region for each of the patterns. If the correction target region is removed from the patterns, the distance between the patterns may comply with the MRC.

Operation S1322 of setting the correction target region may set a correction target region for each pattern such that the area of the correction target region is minimized while a distance between neighboring patterns in the diagonal direction after the removal of the correction target region is greater than or equal to the predetermined distance of the MRC.

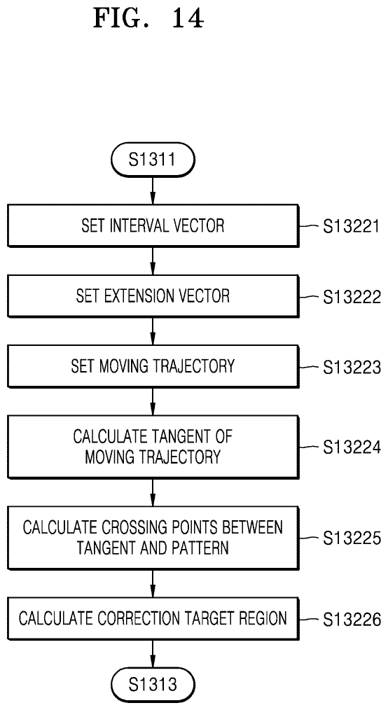

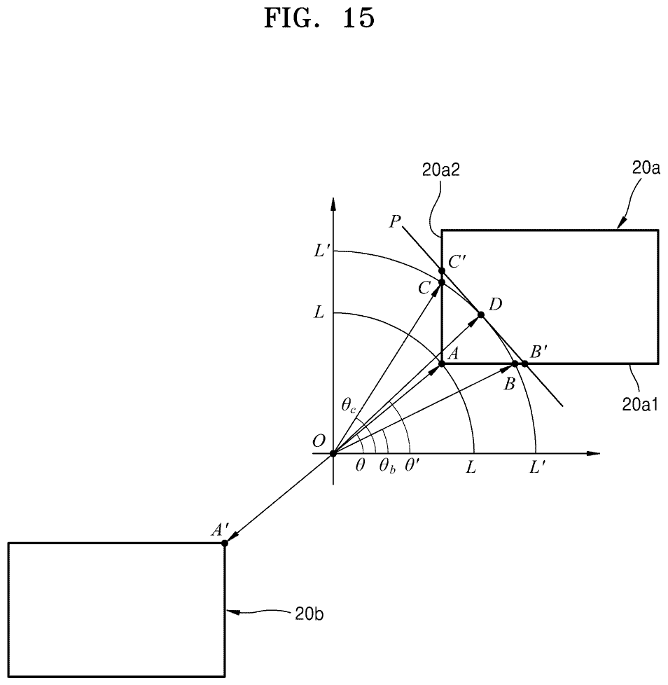

FIG. 14 is a flowchart showing an example operation of setting the correction target region of FIG. 13, and FIG. 15 is a layout diagram of patterns to explain the operation of setting the correction target region of FIG. 14.

Referring to FIG. 14, operation S1322 of setting the correction target region may first set an interval vector between neighboring patterns that overlap each other (S13221). In detail, the interval vector may have a starting point on a line segment connecting opposite vertices (e.g., vertices facing each other) of the diagonally adjacent patterns, may have the same direction as the line segment connecting the vertices, and may have a size of ½ of a length of the line segment.

Referring to FIG. 15, operation S13221 may set a starting point O of the interval vector on a straight line connecting a vertex A of a pattern 20a and a vertex A′ of a pattern 20b between the diagonally neighboring patterns 20a and 20b. The starting point O of the interval vector may be set in a middle section of the straight line connecting the vertex A of the pattern 20a and the vertex A′ of the pattern 20b. A distance between the starting point O and the vertex A may be equal to a distance between the starting point O and the vertex A′.

A size of the interval vector may be ½ of the distance between the patterns 20a and 20b. That is, a length L of the line segment O̅A̅ may be the size of the interval vector. Operation S1312 may set the length L of the line segment O̅A̅ as the size of the interval vector.

A direction of the interval vector may be a direction from the starting point O toward the vertex A of the pattern 20a.

An angle formed by the interval vector with the X-axis may be θ. θ may have 0° to 360°, and as θ changes from 0° to 360°, a trajectory indicated by the end point of the interval vector may be a circle with the starting point of the interval vector as the origin O and the size L of the interval vector as a radius. The circle may touch the vertex A of the pattern 20a and the vertex A′ of the pattern 20b.

Next, an extension vector having the end point of the interval vector as the starting point, the same direction as the interval vector, and a predetermined size may be set (S13222). The size of the extension vector may be set to d. The starting point of the extension vector may be the same as the end point of the interval vector, and the direction of the extension vector may be the same as the direction of the interval vector. An angle θ′ formed by the extension vector with the X-axis may be the same as the angle that the corresponding interval vector forms with the X-axis.

Next, a moving trajectory may be set (S13223). The moving trajectory may denote a trajectory drawn by the end point of the extension vector within the pattern 20a. Specifically, θ′ is the angle between the interval vector and the X-axis as described above and is the angle between the extension vector extended from the interval vector and the X-axis. As θ′ changes from 0° to 360°, the trajectory indicated by the end point of the extension vector may be a circle with the starting point O of the interval vector as the origin and a radius as L′, which is the sum of the size L of the interval vector and the size d of the extension vector. Because the radius of the circle formed by the end point of the extension vector is the sum of the size L of the interval vector and the size d of the extension vector, the circle may overlap with a portion of the pattern 20a as illustrated in FIG. 15. That is, some portion of the trajectory of the end point of the extension vector may be located within the pattern 20a.

Operation S13223 may set an arc [symbol] , which is a trajectory of an end point located within a range of 0° to 90° among the trajectory of the end point of the extension vector located within the pattern 20a.

A point where the end point of the extension vector meets a bottom side 20a1 of the pattern 20a may be B, and a point where the end point of the extension vector meets a left side 20a2 of the pattern 20a may be C. An angle θ_{b} formed by a vector \vec{OB} with the X-axis may be obtained from the following Equation 8. An angle θ_{c} formed by a vector \vec{OC} with the X-axis may be obtained from the following Equation 9.

$${θ}_{b =} {tan}^{- 1} ( \frac{L sin θ}{\sqrt{{( L + d )}^{2} - {( L sin θ )}^{2}}} ) \qquad [ Equation 8 ]$$

$${θ}_{c} = {tan}^{- 1} ( \frac{\sqrt{{( L + d )}^{2} - {( L sin θ )}^{2}}}{L cos θ} ) \qquad [ Equation 9$$

Next, the tangent of a moving trajectory may be obtained (S13224). An equation for obtaining a tangent at a point D, which is the end point of the vector \vec{OD} which is the sum of the interval vector and the extension vector, may be obtained from the following Equation 10.

$$y = - \frac{1}{tan {θ}^{′}} x + ( L + d ) \sqrt{1 + \frac{1}{{tan}^{2} {θ}^{′}}} \qquad [ Equation 10 ]$$

Here, θ′ is an angle of the interval vector with respect to the X-axis, L is a size of the interval vector, and d is a size of the extension vector.

Next, the intersection points where the tangent obtained from Equation 10 meets the pattern 10a may be calculated (S13225).

The intersection points denote points where the tangent meets at least one side of the pattern 20a. Referring to FIG. 15, an intersection point where the tangent meets the bottom side 20a1 of the pattern 20a may be B′, and an intersection point where the tangent meets the left side 20a2 of the pattern 20a may be C′.

Coordinates of the intersection point B′ may be:

$$( tan {θ}^{′} ( ( L + d ) \sqrt{1 + \frac{1}{{tan}^{2} {θ}^{′}}} - L sin θ ) , L sin θ )$$

and coordinates of the intersection point C′ may be:

$$( L cos θ , ( L + d ) \sqrt{1 + \frac{1}{{tan}^{2} {θ}^{′}}} - \frac{L cos θ}{tan {θ}^{′}} )$$

Next, a correction target region may be set (S13226). The correction target region may be a region having the smallest area among regions formed by the line segments connecting the vertex A of the pattern 20a and the intersection points B′ and C′ and the tangent line. The intersection points B′ and C′ may change according to the slope of the tangent line. Accordingly, the region formed by the line segments connecting the vertex A and the intersection points B′ and C′ of the pattern 20a and the tangent line may have various sizes. The correction target region may be a region having the smallest area among the regions formed by the vertex A and the intersection points B′ and C′.

Referring to FIG. 15, a line segment A̅B̅′̅ connecting the vertex A of the pattern 20a and the intersection point B′ may be obtained from the following Equation 11.

$$\overline{{AB}^{′}} = tan {θ}^{′} ( ( L + d ) \sqrt{1 + \frac{1}{{tan}^{2} {θ}^{′}}} - L sin θ ) - L cos θ \qquad [ Equation 11 ]$$

A line segment A̅C̅′̅ connecting the vertex A of the pattern 20a and another intersection point C′ may be obtained from the following Equation 12.

$$\overline{{AC}^{′}} = ( L + d ) \sqrt{1 + \frac{1}{{tan}^{2} {θ}^{′}}} - \frac{L cos θ}{tan {θ}^{′}} - L sin θ \qquad [ Equation 12 ]$$

In the pattern 20a, an area S of the region formed by the line segment A̅B̅′̅, a line segment A̅C̅′̅, and a tangent line B̅′̅C̅′̅ may be obtained from the following Equation 13.

$$[ Equation 13 ]$$

$$S = \text{} \frac{1}{2} \times \overline{{AB}^{′}} \times \overline{{AC}^{′}} = \frac{1}{2} ( ( tan {θ}^{′} ( ( L + d ) \sqrt{1 + \frac{1}{{tan}^{2} {θ}^{′}}} - L sin θ ) - L cos θ ) \text{} ( ( L + d ) \sqrt{1 + \frac{1}{{tan}^{2} {θ}^{′}}} - \frac{L cos θ}{tan {θ}^{′}} - L sin θ )$$

The correction target region in the pattern 20a may be a region having a smallest area S formed by the line segment A̅B̅′̅, the line segment A̅C̅′̅, and the tangent line B̅′̅C̅′̅.

θ′ may be calculated according to θ such that the area S is minimum in a range in which θ′ is greater than or equal to θ_{b} and less than or equal to θ_{c}.

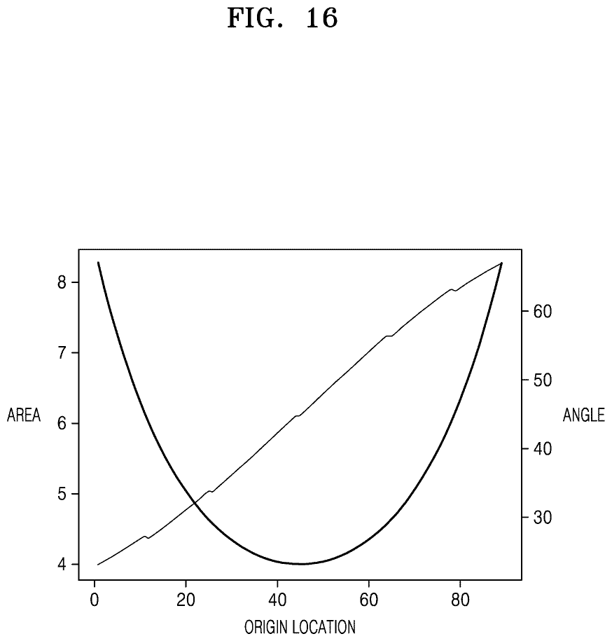

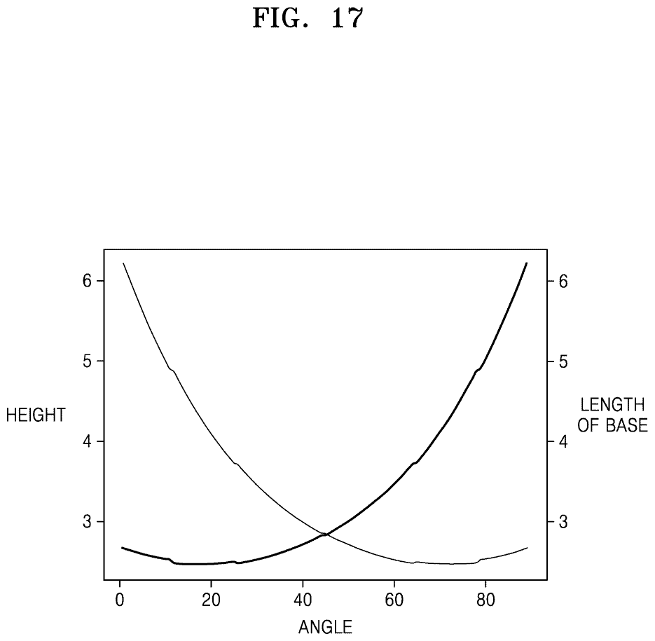

FIG. 16 is a graph showing an area of the correction target region and an angle of an interval vector according to the location of the origin according to an embodiment, and FIG. 17 is a graph showing a height and a length of base of the correction target region according to an angle of the interval vector according to an embodiment.

FIGS. 16 and 17 show a case in which L, which is a size of the interval vector, is 4, d, which is a size of the extension vector, is 2, and θ is 30°.

Referring to FIG. 16, a graph showing the area S according to the location of the origin O is a parabola. It may be confirmed that the area S is minimum when the location of the origin O is approximately 45.

FIG. 17 shows a length of line segment A̅C̅′̅, which is a height of the correction target region according to an angle θ′ and a length of a bottom side A̅B̅′̅. If the angle θ′ is approximately 45°, the length of the line segment AC′ and the length of the bottom side AB′ may have the same value, and in this case, the area S may be minimum.

Next, operation S1323 (see FIG. 13) of removing the correction target region from the pattern 20a may be performed. As described above, the correction target region is a region having the smallest area among regions formed by the line segment A̅C̅′̅, the line segment A̅B̅′̅, and the tangent line B̅′̅C̅′̅ in the pattern 20a. In operation S1323, the correction target region determined in operation S1322 may be removed from the pattern 20a to form a final OPC design layout.

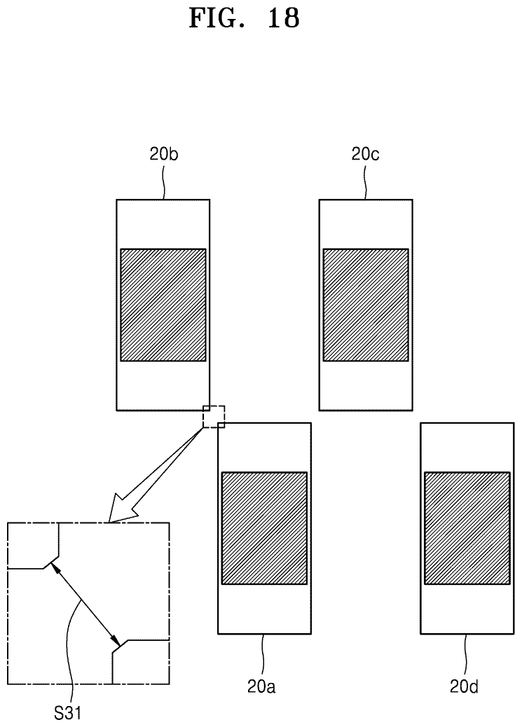

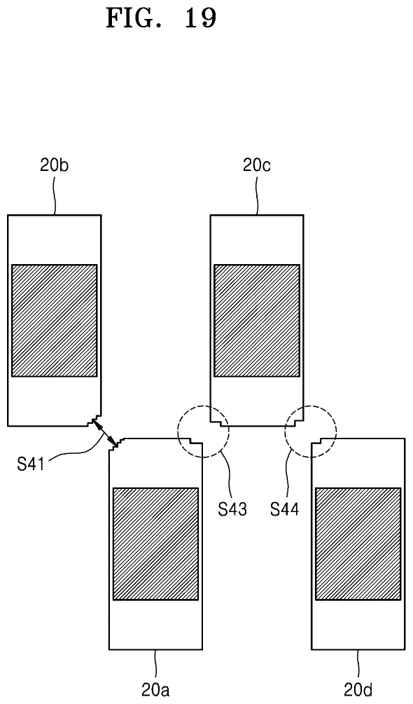

FIG. 18 is a plan view showing patterns from which a portion of the diagonally overlapped patterns is removed according to an embodiment, and FIG. 19 is a plan view showing patterns from which a portion of the pattern is removed according to the related art.

FIG. 18 shows a pattern 20a and a pattern 20b that overlap in a diagonal direction. Referring to FIG. 18, after setting a correction target region as described above because a distance between the pattern 20a and the pattern 20b does not comply with the MRC, the correction target region is removed from the pattern 20a and the pattern 20b. A distance S31 between the pattern 20a and the pattern 20b from which the correction target region is removed complies with the MRC.

A distance between the pattern 20a and a pattern 20c in the diagonal direction and a distance between the pattern 20c and a pattern 20d in the diagonal direction comply with the MRC, and thus, the correction target region is not set or removed for these patterns in relation with each other.

In contrast, referring to FIG. 19, in the related art, a portion of the pattern is removed in a stepwise manner for the entire layout until the MRC is satisfied. According to the related art, some regions of the pattern 20a and the pattern 20b that do not comply with the MRC are removed such that a distance S41 between the pattern 20a and the pattern 20b complies with the MRC. In addition, some regions in a region S43 between the patterns 20a and 20c that comply with the MRC and a region S44 between the patterns 20c and 20d that comply with the MRC may also be removed. Because the related art removes some regions of the patterns without considering the arrangement relationship between the patterns or the optimized angle or size for pattern removal, more regions may be removed than intended in the OPC.

According to an embodiment, for the patterns of the OPCed layout, the arrangement of neighboring patterns may be checked whether the neighboring patterns overlap in the vertical and/or horizontal direction and/or in the diagonal direction, and then, an optimal correction target region is set according to the case of overlapping in the vertical and/or horizontal direction and the case of overlapping in the diagonal direction, and the correction target region may be removed from the patterns, thereby avoiding a removal of unnecessary regions and improving the pattern margin and CD targeting.

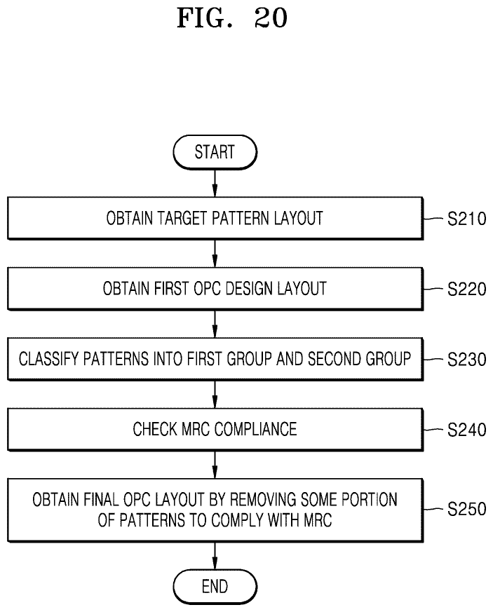

FIG. 20 is a flow chart schematically showing a process of an OPC method according to another embodiment. The embodiment of FIG. 20 will be described with reference to FIGS. 1 to 19, and the descriptions given above with reference to FIGS. 1 to 19 will be briefly described or omitted.

Referring to FIG. 20, the OPC method according to an embodiment may first obtain a design layout for a target pattern to be formed on a substrate (S210). Operation S210 of obtaining the design layout for the target pattern of FIG. 20 may be the same as the method of obtaining the design layout for the target pattern described with reference to FIG. 1.

After receiving the design layout, a first OPC may be performed with respect to the design layout to obtain a first OPC design layout (S220). Operation S220 of performing the first OPC to obtain the first OPC design layout may be the same as operation S110 of obtaining the first OPCed design layout described with reference to FIG. 1.

The patterns of the first OPC design layout may be classified into a first group or a second group (S230). The first group corresponds to a case where neighboring patterns overlap in the vertical and/or horizontal direction, and the second group corresponds to a case where neighboring patterns overlap in the diagonal direction.

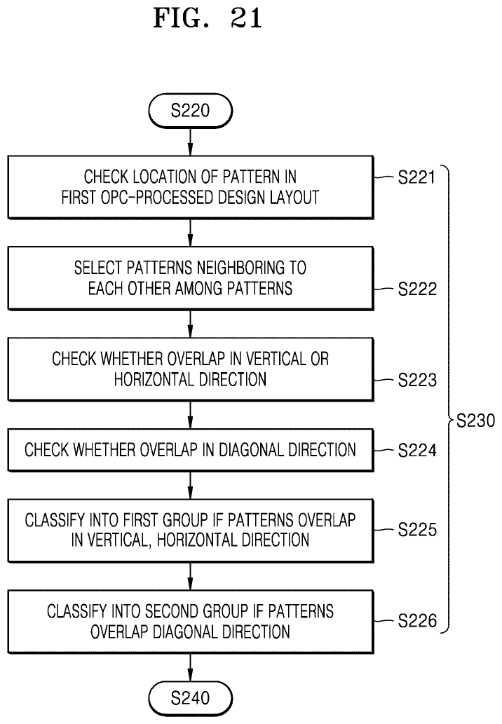

FIG. 21 is a flowchart schematically illustrating an operation of classifying the patterns of FIG. 20 into a first group or a second group.

Referring to FIG. 21, the classification operation S230 may first confirm (or identify) locations of patterns in the first OPCed design layout (S221). The first OPCed design layout may have multiple patterns. In operation S221, location information for each of the multiple patterns in the first OPCed design layout may be detected.

Next, patterns neighboring to each other among the patterns, the locations of which are detected may be selected (S222). In operation S222, for any one pattern among multiple patterns, another pattern neighboring in the vertical and/or horizontal direction may be selected. In addition, for any one pattern among multiple patterns, another pattern neighboring in the diagonal direction may be selected.

Next, it may be determined that whether the patterns selected as neighboring each other overlap in the vertical and/or horizontal direction (S223) and whether they overlap in the diagonal direction (S224). The fact that the neighboring patterns overlap in the vertical and/or horizontal direction denotes that if any one pattern (e.g., 10a in FIG. 3) moves in the vertical direction D1 or the horizontal direction D2, there is a region of that pattern overlapping with the neighboring pattern (e.g., 10b in FIG. 3). Similarly, the fact that neighboring patterns overlap in the diagonal direction denotes that if any one pattern (e.g., 20a in FIG. 4) moves in the diagonal direction, there is a region of that pattern overlapping with the neighboring pattern (e.g., 20b in FIG. 4). Two patterns overlapping in the diagonal direction may not overlap each other in the vertical and/or horizontal direction.

If neighboring patterns overlap in the vertical and/or horizontal direction, the neighboring patterns may be classified into a first group (S225), and if neighboring patterns overlap in the diagonal direction, the neighboring patterns may be classified into a second group (S226).

It may be checked whether a distance between patterns classified into the first group and a distance between patterns classified into the second group comply with the MRC (S240).

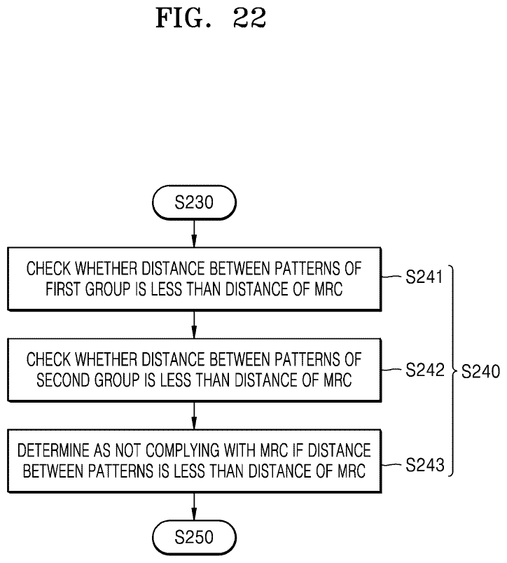

FIG. 22 is a flowchart schematically showing an example of the MRC compliance check operation of FIG. 20.

Referring to FIG. 22, the MRC compliance check operation S240 may include operation S241 of checking whether a distance between patterns overlapping in the vertical and/or horizontal direction for the patterns belonging to the first group is less than a predetermined distance of the MRC, operation S242 of checking whether a distance between the patterns overlapping in the diagonal direction for patterns belonging to the second group is less than a predetermined distance of the MRC, and operation S243 of determining that the distance is not compliance with the MRC if the distance between the patterns is less than a predetermined distance of the MRC.

The operations S241 and S242 of checking whether the distance between the patterns is less than the predetermined distance of the MRC may be the same as the descriptions given with reference to FIGS. 2 to 4.

If the distance between the patterns is determined to be non-compliant with the MRC because the distance is less than the predetermined distance of the MRC, a portion of the pattern may be removed to comply with the MRC (S250).

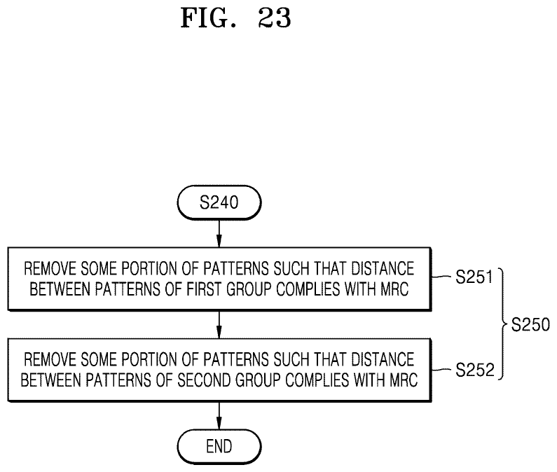

FIG. 23 is a flowchart schematically illustrating an operation of removing a portion of the pattern of FIG. 20.

Referring to FIG. 23, operation S250 of removing a portion of the patterns may include operation S251 of removing a portion of the neighboring patterns such that the distance between neighboring patterns in a region overlapping in the vertical and/or horizontal direction for the patterns belonging to the first group complies with the MRC, and operation S251 of removing a portion of the patterns such that the distance between the neighboring patterns in the diagonal direction for the patterns belonging to the first group complies with the MRC.

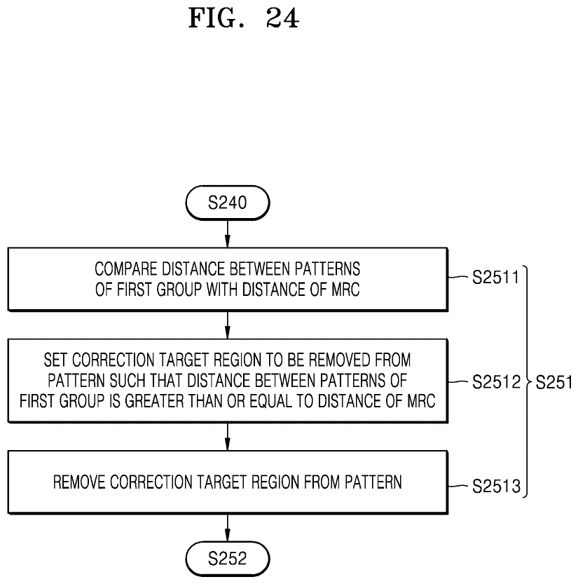

FIG. 24 is a flowchart schematically illustrating an operation of removing a portion of the patterns of the first group of FIG. 23.

Referring to FIG. 24, operation S251 of removing a portion of the patterns belonging to the first group includes operation S2511 of comparing the distance between the patterns with the predetermined distance of the MRC, operation S2512 of setting a correction target region to be removed from the pattern such that the distance between the patterns is greater than or equal to the predetermined distance of the MRC if the distance between the patterns is less than the predetermined distance of the MRC, and operation S2513 of removing the correction target region from the pattern, wherein the operation of setting the correction target region may set a correction target region in which an area of the correction target region is minimized while the distance between the patterns after the correction target region is removed is greater than or equal to the predetermined distance of the MRC. Each operation of operation S251 of removing a portion of the patterns belonging to the first group may be the same as the descriptions given with reference to FIG. 6.

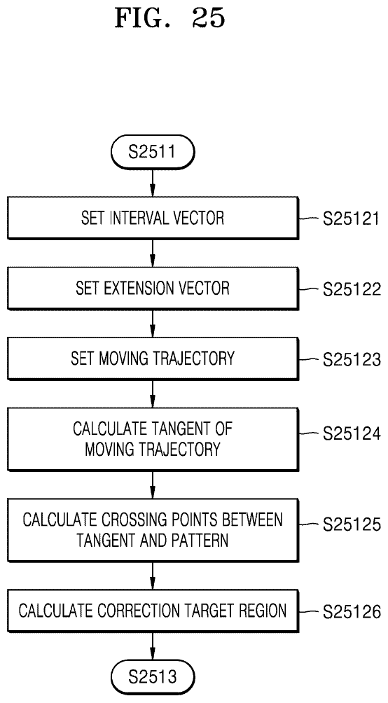

FIG. 25 is a flowchart schematically showing operation S2512 of setting the correction target region of FIG. 24.

Referring to FIG. 25, operation S2512 of setting the correction target region may include operation S25121 of setting an interval vector having a starting point within a region where neighboring patterns overlap in the vertical and/or horizontal direction, having a direction in which the distance between the patterns is minimal, and having a size equal to half of the minimum distance between the patterns, operation S25122 of setting an extension vector having an end point of the interval vector as a starting point, having a direction identical to the interval vector, and having a predetermined size, operation S25123 of setting, as a moving trajectory, a trajectory drawn by the end point of the extension vector within the pattern while the interval vector and the extension vector rotate around the starting point of the interval vector, operation S25124 of obtaining a tangent of the moving trajectory, operation S25125 of obtaining intersection points where the tangent meets the pattern, and operation S25126 of setting a region in which an area formed by a line segment and a tangent connecting the vertices and intersection points of the patterns is minimal as the correction target region. Each operation of operation S2512 of setting the correction target region may be the same as the descriptions given with reference to FIG. 7.

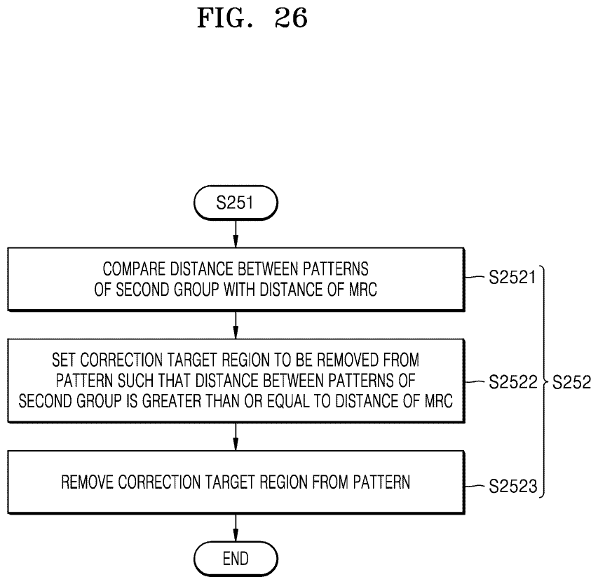

FIG. 26 is a flowchart schematically illustrating operation S252 of removing a portion of the patterns of the second group of FIG. 23.

Referring to FIG. 26, operation S252 of removing a portion of the patterns belonging to the second group may include operation S2521 of comparing the distance between the patterns with the predetermined distance of the MRC, operation S2522 of setting a correction target region to be removed from the pattern such that the distance between the patterns is greater than or equal to the predetermined distance of the MRC if the distance between the patterns is less than the predetermined distance of the MRC, and operation S2523 of removing the correction target region from the pattern, wherein the operation of setting the correction target region may set the correction target region in which an area of the correction target region is minimized while the distance between the patterns after the correction target region is removed is greater than or equal to the predetermined distance of the MRC. Each operation of operation S252 of removing a portion of the patterns of the second group may be the same as the descriptions given with reference to FIG. 13.

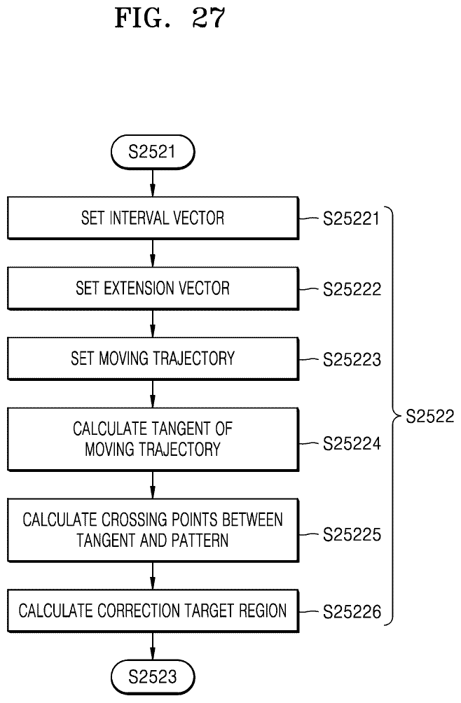

FIG. 27 is a flowchart schematically showing operation S2522 of setting the correction target region of FIG. 26.

Referring to FIG. 27, operation S2522 of setting the correction target region may include operation S25221 of setting an interval vector having a starting point on a line segment connecting vertices facing each other of neighboring patterns, having the same direction as the direction of the line segment connecting the vertices, and having a size equal to half a length of the line segment, operation S25222 of setting an extension vector having the end point of the interval vector as a starting point, having the same direction as the interval vector, and having a predetermined size, operation S25223 of setting, as a moving trajectory, a trajectory drawn by the end point of the extension vector within the pattern when the interval vector and the extension vector rotate around the starting point of the interval vector, operation S25224 of obtaining a tangent of the moving trajectory, operation S25225 of obtaining intersection points where the tangent meets the pattern, and operation S25226 of setting a region having a minimum area formed by the line segment connecting the vertices of the pattern and the intersection points and the tangent as the correction target region. Operation S2522 of setting the correction target region may be the same as the descriptions given with reference to FIG. 16.

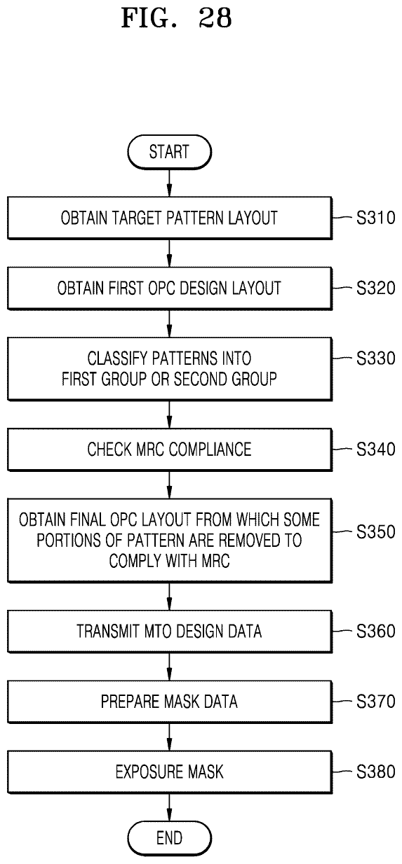

FIG. 28 is a flowchart schematically showing a method of manufacturing a mask including an OPC method according to an embodiment. The embodiment of FIG. 28 will be described with reference to FIGS. 1 to 27 together, and the descriptions already given with reference to FIGS. 1 to 27 will be briefly described or omitted.

Referring to FIG. 28, the method of manufacturing a mask (hereinafter, simply referred to as a mask manufacturing method) including the OPC method, according to an embodiment may sequentially perform from operation S310 of receiving a design layout for a target pattern to operation S350 of obtaining a final OPC pattern. Operation S310 of receiving a design layout for a target pattern to operation S350 of obtaining a final OPC pattern may be the same as or similar to those described for operation S210 of receiving a design layout for a target pattern to operation S250 of obtaining a final OPC pattern of the OPC method of FIG. 20.

Thereafter, MTO design data may be transferred to a mask manufacturing team (S360). In general, MTO may denote transferring data for a final design layout obtained through the OPC method to the mask manufacturing team and requesting mask manufacturing. Therefore, in the mask manufacturing method according to an embodiment, the MTO design data may denote the final OPC pattern obtained through the OPC method, e.g., the OPCed design layout, or data therefor. The MTO design data may have a graphic data format used in electronic design automation (EDA) software, etc. For example, the MTO design data may have a data format such as graphic data system II (GDSII) or an open artwork system interchange standard (OASIS).

Afterwards, a mask data preparation (MDP) may be performed (S370). The mask data preparation may include, for example, i) format conversion called fracturing, ii) augmentation of barcodes for machine reading, standard mask patterns for inspection, job decks, etc., and iii) verification in an automatic or manual manner. Here, the job-deck may denote creating a text file regarding a series of instructions such as layout information of multiple mask files, reference dose, exposure speed or method, etc.

Format conversion, e.g., fracturing, may denote a process of dividing MTO design data into each area and converting the MTO design data into a format for an electron beam exposure machine. The fracturing may include, for example, data manipulation such as scaling, data sizing, data rotation, pattern reflection, and color inversion. In the conversion process through fracturing, data for numerous systematic errors that may occur somewhere during the transfer process from design data to an image on a wafer may be corrected.

A process of correcting data for systematic errors may be called mask process correction (MPC) and may include tasks such as line width adjustment called CD adjustment and improving pattern arrangement precision. Therefore, fracturing may contribute to improving the quality of the final mask and may also be a process performed in advance for mask process correction. Here, systematic errors may be caused by distortions occurring in the exposure process, mask development and etching processes, and wafer imaging processes.

Mask data preparation may include MPC. MPC refers to a process of correcting errors occurring during the exposure process, e.g., systematic errors, as described above. Here, the exposure process may be a concept that comprehensively includes electron beam writing, development, etching, baking, etc. In addition, data processing may be performed before the exposure process. Data processing may be a kind of preprocessing process for mask data, and may include grammar check for mask data, exposure time prediction, etc.

After preparing the mask data, a mask substrate may be exposed based on the mask data (S384). Here, the exposure may denote, for example, electron beam writing. Here, the electron beam writing may be performed using, for example, a gray exposure (Gray Writing) method using a multi-beam mask writer (MBMW). In addition, electron beam writing may be performed using a variable shape beam (VSB) exposure device.

Meanwhile, after the mask data preparation operation, a process of converting the mask data into pixel data may be performed before the exposure process. The pixel data may be data directly used for actual exposure and may include data for a shape to be an exposure target and data for a dose allocated to the exposure target. Here, the data for the shape may be bit-map data in which shape data, which is vector data, is converted through rasterization, etc.

After the exposure process, a series of processes may be performed to complete the mask manufacture (S380). The series of processes may include, for example, processes such as developing, etching, and cleaning. In addition, the series of processes for mask manufacturing may include a metrology process, a defect inspection or defect repair process. Furthermore, the series of processes for mask manufacturing may include a pellicle application process. Here, the pellicle application process may denote a process of attaching a pellicle to a surface of the mask after the final washing and inspection confirms that there are no contaminants or chemical stains to protect the mask from subsequent contamination during delivery of the mask and the usable lifetime of the mask.

While the disclosure has been particularly shown and described with reference to example embodiments thereof, it will be understood that various changes in form and details may be made therein without departing from the spirit and scope of the following claims and their equivalents.

What is claimed is:

1. An optical proximity correction (OPC) method comprising:
obtaining a first OPCed design layout by performing a first OPC on a target design layout;
identifying whether an interval between neighboring patterns in the first OPCed design layout complies with a mask rule check (MRC); and
removing a portion of patterns, among the neighboring patterns, that are determined to not comply with the MRC, such that a distance between the patterns complies with the MRC after the portion is removed.

2. The OPC method of claim 1, wherein the identifying comprises:
identifying whether the neighboring patterns in the first OPCed design layout overlap in at least one of a vertical direction, a horizontal direction, and a diagonal direction;
identifying, based on first patterns among the neighboring patterns overlapping in the vertical direction and/or the horizontal direction, whether a distance between the first patterns complies with the MRC; and
identifying, based on second patterns among the neighboring patterns overlapping in the diagonal direction, whether a distance between the second patterns complies with the MRC.

3. The OPC method of claim 2, wherein the removing comprises:
with respect to the first patterns, removing a portion of the first patterns such that a distance between the first patterns in the vertical direction and/or the horizontal direction after the portion is removed complies with the MRC; and
with respect to the second patterns, removing a portion of the second patterns such that a distance between the second patterns in the diagonal direction after the portion is removed complies with the MRC.

4. The OPC method of claim 3, wherein the removing the portion of the first pattern comprises:
comparing the distance between the first patterns with a predetermined distance of the MRC;
based on the distance between the first patterns being less than the predetermined distance, setting a correction target region to be removed from each of the first patterns such that the distance between the first patterns after the correction target region is removed is greater than or equal to the predetermined distance; and
removing the correction target region from each of the first patterns,
wherein the setting the correction target region comprises setting the correction target region having a smallest area while the distance between the first patterns after the correction target region is removed is greater than or equal to the predetermined distance.

5. The OPC method of claim 4, wherein the setting of the correction target region comprises:
setting an interval vector having a starting point within a region where the first patterns overlap in the vertical direction and/or the horizontal direction, having a size of ½ of a minimum distance between the first patterns, and having a direction from the starting point toward one of the first patterns;
setting an extension vector having an end point of the interval vector as a starting point, having a same direction as the interval vector, and having a predetermined size;
setting, as a moving trajectory, a trajectory drawn by an end point of the extension vector within the one of the first patterns while the interval vector and the extension vector rotate with the starting point of the interval vector as a center;
obtaining a tangent of the moving trajectory;
obtaining intersection points where the tangent meets the one of the first patterns; and
setting, as the correction target region, a region where an area of the region formed by a line segment connecting vertices of the one of the first patterns, the intersection points, and the tangent is minimum.

6. The OPC method of claim 3, wherein the removing the portion of the second patterns comprises:
comparing the distance between the second patterns with a predetermined distance of the MRC;
based on the distance between the second patterns being less than the predetermined distance, setting a correction target region to be removed from the second patterns such that the distance between the second patterns after the correction target region is removed is greater than or equal to the predetermined distance; and
removing the correction target region from each of the second patterns,
wherein the setting of the correction target region comprises setting the correction target region having a smallest area while the distance between the second patterns after the correction target region is removed is greater than or equal to the predetermined distance.

7. The OPC method of claim 6, wherein the setting the correction target region comprises:
setting an interval vector having a starting point on a line segment connecting opposite vertices of one of the second patterns, having a same direction as a direction of the line segment connecting the opposite vertices, and having a size equal to half a length of the line segment;
setting an extension vector having an end point of the interval vector as a starting point, having a same direction as the interval vector, and having a predetermined size;
setting, as a moving trajectory, a trajectory drawn by an end point of the extension vector within the one of the second patterns while the interval vector and the extension vector rotate with the starting point of the interval vector as a center;
obtaining a tangent of the moving trajectory;
obtaining intersection points where the tangent meets the one of the second patterns; and
setting, as the correction target region, a region where an area of the region formed by the line segment connecting the opposite vertices of the one of the second patterns, the intersection points, and the tangent is minimum.

8. An optical proximity correction (OPC) method comprising:
receiving a design layout for a target pattern;
obtaining a first OPCed design layout by performing a first OPC with respect to the design layout;
classifying neighboring patterns into a first group and a second group according to a relationship between locations of the neighboring patterns, the neighboring patterns being spaced apart from each other in the first OPCed design layout;
identifying whether a distance between first patterns classified into the first group or second patterns classified into the second group complies with a mask rule check (MRC); and
based on the distance between the first patterns or the second patterns not complying with the MRC, removing a portion of the first patterns or the second patterns such that the distance between the first patterns or the second patterns after the portion is removed complies with the MRC,
wherein neighboring patterns that overlap in a vertical direction and/or a horizontal direction are classified into the first group, and
wherein neighboring patterns that overlap in a diagonal direction are classified into the second group.

9. The OPC method of claim 8, wherein the classifying includes:
identifying locations of patterns in the first OPCed design layout;
selecting the neighboring patterns based on the locations of the patterns;
identifying whether the neighboring patterns overlap in the vertical direction and/or the horizontal direction; and
identifying whether the neighboring patterns overlap in the diagonal direction.

10. The OPC method of claim 9, wherein the identifying includes:
identifying whether the distance between the first patterns belonging to the first group is less than a predetermined distance of the MRC;
identifying whether the distance between the second patterns belonging to the second group is less than the predetermined distance; and
based on the distance between the first patterns or the second patterns being less than the predetermined distance, determining that the distance between the first patterns or the second patterns not complying with the MRC.

11. The OPC method of claim 8, wherein the removing includes:
removing a portion of the first patterns such that the distance between the first patterns belonging to the first group complies with the MRC; and
removing a portion of the second patterns such that the distance between the second patterns belonging to the second group complies with the MRC.

12. The OPC method of claim 11, wherein the removing the portion of the first patterns belonging to the first group includes:
comparing the distance between the first patterns with a predetermined distance of the MRC;
based on the distance between the first patterns being less than the predetermined distance, setting a correction target region to be removed from each of the first pattern such that the distance between the first patterns after the correction target region is removed is greater than or equal to the predetermined distance; and
removing the correction target region from each of the first patterns,
wherein the setting the correction target region comprises setting the correction target region having a smallest area while the distance between the first patterns after the correction target region is removed is greater than or equal to the predetermined distance.

13. The OPC method of claim 12, wherein the setting the correction target region comprises:
setting an interval vector having a starting point within a region where the first patterns overlap in the vertical direction and/or the horizontal direction, having a size of ½ of a minimum distance between the first patterns, and having a direction from the starting point toward one of the first patterns;
setting an extension vector having an end point of the interval vector as a starting point, having a same direction as the interval vector, and having a predetermined size;
setting, as a moving trajectory, a trajectory drawn by the end point of the extension vector within the one of the first patterns while the interval vector and the extension vector rotate with the starting point of the interval vector as a center;
obtaining a tangent of the moving trajectory;
obtaining intersection points where the tangent meets the one of the first patterns; and
setting, as the correction target region, a region where an area of the region formed by a line segment connecting vertices of the one of the first patterns, the intersection points, and the tangent is minimum.

14. The OPC method of claim 11, wherein the removing the portion of the second patterns belonging to the second group comprises:
comparing the distance between the second patterns with a predetermined distance of the MRC;
based on the distance between the second patterns being less than the predetermined distance, setting a correction target region to be removed from each of the second patterns such that the distance between the second patterns after the correction target region is removed is greater than or equal to the predetermined distance; and
removing the correction target region from each of the second patterns,
wherein the setting the correction target region comprises setting the correction target region having a smallest area while the distance between the second patterns after the correction target region is removed is greater than or equal to the predetermined distance.

15. The OPC method of claim 14, wherein the setting the correction target region comprises:
setting an interval vector having a starting point on a line segment connecting opposite vertices of one of the second patterns, having a same direction as a direction of the line segment connecting the opposite vertices, and having a size equal to half a length of the line segment;
setting an extension vector having an end point of the interval vector as a starting point, having a same direction as the interval vector, and having a predetermined size;
setting, as a moving trajectory, a trajectory drawn by an end point of the extension vector within the one of the second patterns while the interval vector and the extension vector rotate with the starting point of the interval vector as a center;
obtaining a tangent of the moving trajectory;
obtaining intersection points where the tangent meets the one of the second patterns; and
setting, as the correction target region, a region where an area of the region formed by a line segment connecting opposite vertices of the one of the second patterns, the intersection points, the tangent is minimum.

16. A mask manufacturing method comprising:
receiving a design layout for a target pattern;
obtaining a first optical proximity correction (OPC)-ed design layout by performing a first OPC on the design layout;
classifying neighboring patterns into a first group and a second group according to a relationship between locations of the neighboring patterns, the neighboring patterns being spaced apart from each other in the first OPCed design layout;
identifying whether a distance between first patterns classified into the first group or second patterns classified into the second group complies with a mask rule check (MRC);
based on the distance between the first patterns or the second patterns not complying with the MRC, obtaining a final OPC layout by removing a portion of the first patterns or second portions to comply with the MRC;
transmitting data for the final OPC layout as mask tape-out (MTO) design data;
preparing mask data based on the MTO design data; and
performing exposure on a mask substrate based on the mask data,
wherein the classifying the neighboring patterns comprises:
identifying locations of the patterns in the first OPCed design layout;
selecting the neighboring patterns based on the locations of the patterns;
identifying whether the neighboring patterns overlap in a vertical direction and/or a horizontal direction;
identifying whether the neighboring patterns overlap in a diagonal direction;
classifying the neighboring patterns that overlap in the vertical direction and/or the horizontal direction into the first group; and
classifying the neighboring patterns that overlap in the diagonal direction into the second group.

17. The mask manufacturing method of claim 16, wherein the removing the portion of the first patterns belonging to the first group includes:
comparing a distance between the first patterns with a predetermined distance of the MRC;
based on the distance between the first patterns being less than the predetermined distance, setting a correction target region to be removed from each of the first patterns such that the distance between the first patterns after the correction target region is removed is greater than or equal to the predetermined distance; and
removing the correction target region from each of the first patterns,
wherein the setting the correction target region comprises setting the correction target region having a smallest area while the distance between the first patterns after the correction target region is removed is greater than or equal to the predetermined distance.

18. The mask manufacturing method of claim 17, wherein the setting the correction target region comprises:
setting an interval vector having a starting point within a region where the first patterns overlap in the vertical direction and/or the horizontal direction, having a size of ½ of a minimum distance between the first patterns, and having a direction from the starting point toward one of the first patterns;
setting an extension vector having an end point of the interval vector as a starting point, having a direction same as the interval vector, and having a predetermined size;
setting, as a moving trajectory, a trajectory drawn by an end point of the extension vector within the one of the first patterns while the interval vector and the extension vector rotate with the starting point of the interval vector as a center;
obtaining a tangent of the moving trajectory;
obtaining intersection points where the tangent meets the one of the first patterns; and
setting, as the correction target region, a region where an area of the region formed by a line segment connecting vertices of the one of the first patterns, the intersection points, and the tangent is minimum.

19. The mask manufacturing method of claim 16, wherein the removing the portion of the second patterns belonging to the second group comprises:
comparing the distance between the second patterns with a predetermined distance of the MRC;
based on the distance between the second patterns being less than the predetermined distance, setting a correction target region to be removed from each of the second patterns such that the distance between the second patterns after the correction target region is removed is greater than or equal to the predetermined distance; and
removing the correction target region from each of the second patterns,
wherein the setting of the correction target region comprises setting the correction target region having a smallest area while the distance between the second patterns after the correction target region is removed is greater than or equal to the predetermined distance.

20. The mask manufacturing method of claim 19, wherein the setting the correction target region comprises:
setting an interval vector having a starting point on a line segment connecting opposite vertices of one of the second patterns, having a same direction as a direction of the line segment connecting the opposite vertices, and having a size equal to half a length of the line segment;
setting an extension vector having an end point of the interval vector as a starting point, having a same direction as the interval vector, and having a predetermined size;
setting, as a moving trajectory, a trajectory drawn by an end point of the extension vector within the one of the second patterns while the interval vector and the extension vector rotate with the starting point of the interval vector as a center;
obtaining a tangent of the moving trajectory;
obtaining intersection points where the tangent meets the one of the second patterns; and
setting, as the correction target region, a region where an area of a region formed by the line segment connecting the opposite vertices of the one of the second patterns, the intersection points, and the tangent is minimum.
